(19) United States
(12) Patent Application Publication
(10) Pub. No.: US 2026/0349063 A1
(43) Pub. Date: Nov. 5, 2026

(54) METHOD FOR VERIFYING COMPOSITE MEASUREMENT ACCURACY IN ELECTRICITY METER AND CURRENT TRANSFORMER ASSEMBLIES

(71) Applicant: Accuenergy (Canada) Inc., Toronto (CA)

(72) Inventors: Yufan Wang, Toronto (CA); Ketao Li, Toronto (CA); Liang Wang, Toronto (CA)

(73) Assignee: Accuenergy (Canada) Inc., Toronto (CA)

(21) Appl. No.: 19/196,885

(22) Filed: May 2, 2025

(51) Int. Cl. G01R 35/00; G01R 21/133

(52) U.S. Cl. CPC G01R 35/005; G01R 21/133

(57) ABSTRACT

A method is provided for verifying the composite measurement accuracy of an electricity metering assembly comprising an electricity meter and a current transformer (CT). The method includes measuring a secondary current output from the CT under defined load conditions using at least one current sensing component. A processing unit determines a CT ratio error based on a comparison between the measured secondary current and a theoretical value derived from a known primary current. A phase angle detection unit measures phase displacement between the primary and secondary currents. The electricity meter acquires energy measurement values under reference operating conditions, including voltage, current, frequency, power factor, and temperature. A composite measurement accuracy value is computed by combining the CT ratio error, phase displacement, and energy deviation from expected reference values. The result is used to verify installation quality, support calibration traceability, and assess the long-term reliability of the metering assembly.

### FIELD OF THE INVENTION

The present invention relates to the field of electricity metering systems, and more particularly, to methods for verifying the composite measurement accuracy of metering assemblies comprising an electricity meter and a current transformer (CT), by evaluating and combining multiple sources of measurement error under defined operating conditions.

### BACKGROUND

Electricity metering systems are widely used in utility, industrial, and commercial settings to measure electrical energy consumption for billing, monitoring, and regulatory compliance purposes. In many installations, especially where high current is present, the metering assembly includes both an electricity meter and an external current transformer (CT) for isolating and scaling the current before measurement. The overall accuracy of such a system depends not only on the performance of the electricity meter but also on the accuracy of the CT and the interaction between the two.

Traditionally, the CT and the meter are calibrated and tested separately under laboratory conditions, with each device being assigned to its own accuracy class in accordance with standards such as IEC 62053 or ANSI C12. However, this segmented approach does not account for the cumulative or interactive effects of measurement errors introduced by the CT and meter when used together in the field. As a result, the actual measurement accuracy of the combined system under real-world conditions may deviate from the expectations implied by individual device certifications.

Existing methods lack a practical and standardized approach for evaluating the composite accuracy of the CT-meter combination during installation, commissioning, or periodic verification. Furthermore, they often fail to incorporate dynamic influences such as ratio error, phase displacement, and meter-specific energy deviations under defined operating conditions. Without an integrated methodology for assessing these parameters collectively, installation errors, calibration drift, or misaligned components may go undetected, leading to inaccurate billing, regulatory non-compliance, and system reliability issues.

Accordingly, there is a need for a method that can determine the composite measurement accuracy of an electricity metering assembly by directly measuring CT-related and meter-related error parameters under specified conditions, combining those values into a single accuracy metric, and using the result to verify installation quality, support calibration traceability, or assess long-term performance.

### SUMMARY OF THE INVENTION

The present invention provides a method for verifying the composite measurement accuracy of an electricity metering assembly that includes an electricity meter and a current transformer (CT). Unlike traditional approaches that assess meter and CT accuracy in isolation, the disclosed method evaluates multiple sources of error simultaneously to produce a unified metric reflecting the performance of the combined system under defined conditions.

The method involves measuring the CT's secondary current output under controlled load conditions using a current sensing component. A processing unit determines the CT's ratio error by comparing this measured value with a theoretical secondary current calculated from a known primary current and the CT's nominal turns ratio. A phase angle detection unit is used to identify the phase displacement between the primary and secondary current waveforms.

Concurrently, the electricity meter acquires energy measurement data under reference operating conditions, which include specified voltage, current, frequency, power factor, and ambient temperature. A computation stage then integrates the CT ratio error, phase displacement, and the deviation between the meter's measured energy values and expected reference values to determine a composite measurement accuracy value. This value serves as a basis for assessing whether the metering assembly meets accuracy expectations in its installed configuration.

The calculated composite value can be used to verify installation quality, support traceable calibration procedures, and evaluate the ongoing measurement reliability of the CT-meter assembly. This method provides a practical and comprehensive approach for validating metering system performance in field, laboratory, or production environments, and addresses the limitations of conventional testing techniques that overlook the interaction between CT and meter components.

### BRIEF DESCRIPTION OF THE DRAWINGS

FIG. 1 is a flowchart illustrating a method for verifying the composite measurement accuracy of an electricity metering assembly including an electricity meter and a current transformer,

### DETAILED DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimension, and materials are illustrated for the various elements, those skilled in the art will recognize that many of the examples provided have suitable alternatives that may be utilized.

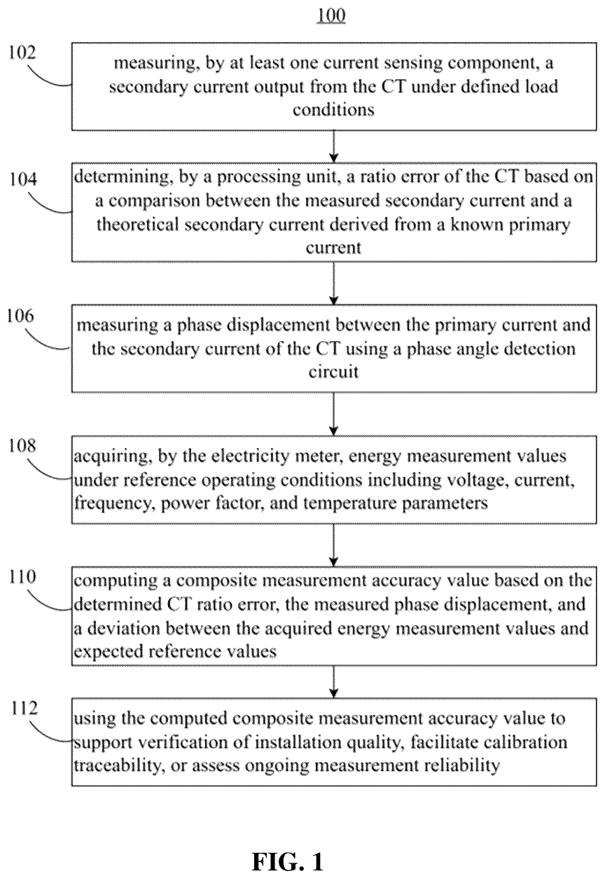

Referring to FIG. 1, the present invention provides a method for verifying the composite measurement accuracy of an electricity metering assembly comprising an electricity meter and a current transformer (CT). The method may be implemented using a combination of sensing hardware, measurement circuitry, and processing logic designed to perform the steps shown in Blocks 102 to 112.

In Block 102, the method begins by measuring, using at least one high-accuracy current sensing component, the secondary current output from the CT under defined electrical load conditions. The current sensing component is an independent device, physically and electrically separate from the CT under test, and is used exclusively to capture the actual current being output by the CT's secondary winding. Suitable current sensing components include high-precision current shunts, zero-flux (compensated) current transducers, or high-resolution current measurement modules designed for metrological-grade applications.

The CT under test is energized by applying a known primary current to its primary conductor. This current may be generated by a programmable current source, a reference current injection system, or a precision load setup capable of providing sinusoidal current across a range of test amplitudes. The primary current waveform is typically synchronized with the system voltage and maintained at nominal test conditions, such as 10%, 100%, or 120% of the CT's rated primary current.

The secondary output of the CT, typically 1 A or 5 A nominal depending on its rating, is routed through the independent current sensing component, which is connected in series within the CT's secondary circuit. This component is designed to measure the root mean square (RMS) value of the current or to sample the waveform in real time. For waveform sampling, the sensing component is connected to a high-resolution analog-to-digital conversion (ADC) system—for example, a 24-bit sigma-delta ADC with a sampling rate of at least 2 kHz—sufficient to accurately resolve the current waveform including its fundamental and harmonic components.

To ensure that the measurement reflects true CT performance, signal conditioning may be applied. This includes anti-aliasing filters, thermal compensation, and digital averaging over several cycles to minimize transient fluctuations. The resulting digitized secondary current is then buffered and prepared for comparison against the theoretical secondary current.

The theoretical secondary current is calculated by dividing the known, injected primary current by the CT's nominal turns ratio. For example, a CT with a 100:5 turns ratio and a 50 A primary current would be expected to produce 2.5 A on the secondary. The difference between the measured and theoretical secondary currents is computed as a ratio error, typically expressed as a percentage deviation relative to the theoretical value.

This setup ensures that the CT's transformation accuracy is captured under realistic operating conditions, with all test equipment traceable to certified calibration standards. The accuracy of the sensing component used in this block must exceed the expected performance of the CT under test to ensure that the computed ratio error reflects true CT behavior and not measurement uncertainty.

In Block 104, the method proceeds by determining, through a processing unit, the CT ratio error, which characterizes the amplitude-based deviation of the current transformer under test. This error quantifies how closely CT's actual transformation performance matches the expected ideal output based on its rated turns ratio. The processing unit receives two key inputs for this purpose: the measured secondary current and the theoretical secondary current. The measured secondary current is obtained from the high-accuracy current sensing component described in Block 102, which provides either a real-time waveform sample or an RMS-calculated value corresponding to the CT's output under test conditions. The theoretical secondary current is derived by dividing the known primary current applied to the CT by the CT's nominal or certified turns ratio. For example, a CT rated at 100:5 subjected to a primary current of 50 A should ideally output 2.5 A on its secondary winding.

Once the two values are available, the processing unit calculates the CT ratio error as the percentage deviation of the measured secondary current from the theoretical value. The ratio error is computed using the standard expression:

$$\frac{( {I}_{measured} - {I}_{theoretical} )}{{I}_{theoretical}} \times 100$$

A positive result indicates that the CT is outputting more current than expected, whereas a negative result indicates underperformance. To ensure measurement stability, the processing unit may apply averaging or digital filtering across multiple AC cycles to reduce the influence of transient disturbances or measurement noise. These operations may include RMS computation over fixed-length sampling windows, low-pass filtering, or digital decimation of high-frequency data.

The processing unit responsible for executing these steps may be implemented as a microcontroller (MCU), a digital signal processor (DSP), a field-programmable gate array (FPGA), or as part of an embedded CPU in a calibration device, smart meter, or verification tool. In all cases, the processing unit must be configured to support the acquisition of synchronized input signals for both the primary and secondary current paths. It should include memory resources for storing test configuration parameters, the CT turns ratio, and calibration constants. The processing logic must support real-time or near-real-time arithmetic operations, including subtraction, division, and scaling, with sufficient numerical resolution to avoid rounding or quantization errors that could affect the error calculation outcome.

The processing unit may be programmed to receive current values from analog-to-digital converters connected to precision current transducers. It is preferred that the current sensing channels be synchronized in time, or that appropriate interpolation or alignment methods be applied to ensure valid comparisons between the primary and secondary signals. After computing the CT ratio error, the processing unit can retain the result in memory, forward it to a computation unit for further use in composite accuracy calculation, or expose it via a digital communication interface for inspection, logging, or reporting.

This implementation ensures that the processing unit serves as a reliable, repeatable, and configurable platform for accurately evaluating CT's amplitude transformation performance under known test conditions. The resulting CT ratio error value forms one of the foundational components in the composite measurement accuracy assessment of the metering assembly.

In Block 106, the method includes measuring the phase displacement between the primary current and the secondary current using a phase angle detection unit. This measurement is essential for identifying the angular error introduced by the current transformer (CT) during the transformation of alternating current from its primary to secondary winding. The phase displacement represents the time-based shift between the waveforms of the primary and secondary currents and is expressed as an angular deviation in electrical degrees. Such phase displacement affects the accuracy of active energy measurement, particularly under non-unity power factor conditions, and therefore must be accounted for when verifying the overall composite accuracy of the metering assembly.

To carry out this measurement, the phase angle detection unit receives both the primary current and the secondary current waveforms as input. These waveforms may be delivered as analog signals or, preferably, as digitized samples acquired by synchronized analog-to-digital converters. The circuit may be implemented in various forms depending on the system architecture. One practical approach is to use a digital signal processor (DSP) or microcontroller with real-time data acquisition capabilities and embedded trigonometric or time-domain comparison routines. The processor is configured to compute the relative phase shift between the zero-crossings of the primary and secondary current waveforms, or by performing cross-correlation or Fourier-based phase estimation across the waveform segments.

In digital implementations, the waveform data are captured over several cycles of the fundamental frequency (typically 50 Hz or 60 Hz), and processed in a windowed time base to detect periodic zero-crossings or compute the instantaneous phase angle at a reference point in each waveform. The circuit then calculates the phase displacement as the angular difference between the primary and secondary waveforms. This value may be determined in degrees or radians and may also be normalized to a full electrical cycle to account for multiple harmonics. The resulting phase error is typically small—on the order of tenths of a degree—but is significant in high-accuracy applications, especially when reactive power components influence the meter's reading.

In hardware-based systems, the phase angle detection unit may also be realized using discrete analog comparators and timing logic. For example, zero-crossing detectors may trigger timers that measure the time interval between equivalent points in the primary and secondary current waveforms. This time difference is then converted to an angular displacement using the known waveform period. For a 60 Hz signal, one cycle equals 16.67 milliseconds; therefore, a 1 millisecond lag corresponds to approximately 21.6 degrees of phase shift. While analog implementations are feasible, digital systems are generally preferred due to their flexibility, programmability, and immunity to component drift and analog noise.

The implementation must ensure that both input channels—corresponding to the primary and secondary current paths—are sampled with synchronized clocks or corrected for sample offset, jitter, or latency differences. In high-precision systems, signal alignment techniques such as interpolation or oversampling may be applied to further refine the phase angle resolution. Environmental influences such as temperature drift, waveform distortion, and external interference should also be mitigated through hardware shielding and digital noise suppression.

Once computed, the measured phase displacement is output by the phase angle detection unit and made available to the system's computation unit for use in the composite accuracy calculation. The measured phase error is not interpreted in isolation, but rather as one of the contributing components to the total measurement deviation of the meter and CT combination.

This implementation provides a robust, scalable, and traceable means of measuring CT-induced phase error in practical test environments and allows metering manufacturers, utility operators, or third-party calibration entities to incorporate phase displacement effects into comprehensive system-level accuracy assessments.

In Block 108, the electricity meter under test is used to acquire energy measurement values under defined reference operating conditions. These conditions are standardized to ensure comparability across devices and traceability to international metrology requirements, and they serve as the baseline for determining how accurately the meter records electrical energy. The energy measurement is typically captured over a controlled time interval while maintaining all input parameters within a specified range. These parameters include the input voltage, current, frequency, power factor, and ambient temperature, each of which may influence the accuracy of the energy registration function.

The input voltage is supplied from a stabilized AC voltage source or power calibrator, with the magnitude adjusted to nominal levels appropriate to the meter class, such as 120 V, 230 V, or another rated value. The voltage must be maintained within a narrow tolerance band (e.g., +1%) to simulate ideal test conditions. Likewise, the current is injected through the CT under test and routed through the meter's current input terminals. The magnitude of the current is selected from a range of predefined test points—such as 5%, 10%, 100%, or 120% of the rated current—to assess the meter's response across its dynamic operating range.

The frequency is fixed, typically at either 50 Hz or 60 Hz, depending on the region, and is generated using a frequency-stable voltage/current source or power calibrator. The power factor is adjusted using controlled resistive, inductive, or capacitive loading or by programming the phase shift between voltage and current waveforms in the test system. A typical test may be performed at unity power factor as well as under lagging or leading power factor conditions (e.g., 0.5 lagging). Ambient temperature is maintained or monitored within a tightly controlled range (e.g., 23 °C±2 °C), using climate chambers or laboratory conditions, to reduce thermal effects on measurement accuracy.

During the test, the electricity meter under evaluation operates in a normal measurement mode, and the total amount of active energy (in kilowatt-hours or watt-hours) delivered over the test interval is accumulated by the meter. The length of the interval may vary but is typically long enough to ensure statistical stability, such as several seconds to several minutes. The energy value reported by the meter under test is recorded by the system.

Simultaneously, a traceable calibrated reference meter is used to perform the same energy measurement over the same test interval and under identical input conditions. The reference meter is a high-accuracy device with a calibration certificate traceable to national or international metrology institutes (e.g., NIST, PTB), with a known uncertainty class substantially better than that of the meter under test. The reference meter may be integrated into the test bench or used as a standalone verification tool and is connected in parallel with the meter under test so that both devices experience the same voltage and current inputs.

After the test interval ends, the energy value recorded by the reference meter is compared against the value recorded by the meter under test. The energy measurement deviation is calculated as the percentage difference between the two results. This deviation reflects any bias, nonlinearity, or systemic error present in the energy registration process of the tested meter under controlled conditions. The result is expressed as:

$$Energy Deviation ( \% ) = \frac{{E}_{meter \_ under \_ test} - {E}_{reference \_ meter}}{{E}_{reference \_ meter}} \times 100$$

This deviation value is then supplied to the system's computation logic as one of the key inputs used in the composite measurement accuracy calculation described in later blocks.

In Block 110, a computation unit calculates a composite measurement accuracy value that quantitatively represents the total measurement error introduced by the combined operation of the current transformer (CT) and the electricity meter. This value integrates the three main sources of measurement error identified in earlier steps: the CT ratio error, the CT phase displacement error, and the energy deviation of the meter. The purpose of this calculation is to consolidate the component-level measurement uncertainties into a single result that characterizes the system-level accuracy of the entire metering assembly under test conditions.

The computation unit receives as inputs: (1) the CT ratio error determined in Block 104, which reflects the amplitude error of the CT; (2) the phase displacement between the primary and secondary current waveforms measured in Block 106, which affects the accuracy of active energy measurement depending on power factor; and (3) the energy deviation of the meter under reference conditions as determined in Block 108, which reflects the intrinsic accuracy or bias of the meter itself. These three error sources are all expressed as percentages and are treated as independent variables, though their combined effect on energy accuracy may be interrelated.

The computation unit processes these values using a mathematical expression that combines them in a weighted quadratic form. A preferred implementation uses the following equation:

S=\sqrt{w₁×E₁²+w₂×E₂²+w₃×E₃²}

In this equation, S is the composite measurement accuracy value; E₁ is the CT ratio error; E₂ is the phase displacement error, converted into an equivalent energy error percentage based on a predetermined power factor condition such as 0.5 lagging; E₃ is the energy deviation of the electricity meter; and w₁, w₂, and w₃ are weighting coefficients that reflect the relative contribution of each component to overall active energy measurement error. The square root of the weighted sum of squares provides a norm-like metric that aggregates the errors while preserving their magnitude significance.

The weighting coefficients may be empirically derived based on laboratory characterization data, industry standards, or application-specific tolerances. For example, in commercial billing applications, the CT ratio error may be assigned a higher weight due to the critical importance of current accuracy over a wide dynamic range. In other scenarios, such as reactive load environments, the phase displacement error may be weighted more heavily due to its influence on active energy under poor power factor conditions. The computation unit may store these coefficients in memory or retrieve them dynamically based on a selected metering class or test profile.

The computation unit itself may be implemented using a microprocessor, digital signal processor (DSP), or embedded system configured to execute floating-point or fixed-point arithmetic. It may be integrated within the same hardware platform as the processing unit described in earlier blocks or operate as a separate subsystem. The computation unit accesses buffered inputs, performs the necessary mathematical operations, and outputs the result to a designated memory location, user interface, or communication port.

In a digital system, the computation may be executed within a firmware loop or interrupt-driven routine, ensuring that the composite value is generated in real-time or at the end of each test cycle. Safeguards may be included to validate the input ranges before computation, and exception handling routines may be provided in the event of missing, corrupted, or nonsensical data. Once computed, the composite measurement accuracy value is passed to the next step for evaluation and classification.

This implementation enables a robust and consistent framework for assessing the combined accuracy performance of the CT and meter assembly, providing utilities, manufacturers, or field technicians with a single, actionable metric that reflects whether the metering assembly conforms to required accuracy specifications under actual or simulated operating conditions.

In Block 112, the computed composite measurement accuracy value is utilized to support various downstream applications, including verification of installation quality, facilitation of calibration traceability, and assessment of ongoing measurement reliability. Once the value is calculated by the computation unit as described in Block 110, it is transferred to an output stage that allows the user, system, or quality assurance process to interpret and act upon the result.

One primary use of the composite measurement accuracy value is to determine whether the assembled metering system—comprising the electricity meter and the associated current transformer—conforms to a predefined accuracy class. This evaluation involves comparing the computed value against an established acceptance threshold defined by regulatory standards, internal quality criteria, or application-specific requirements. For example, if the computed composite error is less than or equal to 0.5%, the system may be classified as meeting Class 0.5 accuracy performance. If the error exceeds the threshold, the system may be flagged as non-compliant.

The evaluation logic may be implemented in firmware or software and may be configured to automatically classify each metering assembly as passing or failing based on the computed result. In the event of a failure, the system may initiate additional diagnostics or alert the user that the installation requires corrective action. Such actions may include recalibration of the electricity meter, replacement of the CT, verification of wiring or connection polarity, or adjustment of test parameters. These decisions may be guided by comparing the individual components of the composite error—such as identifying whether the dominant source of deviation originates from CT ratio error, phase error, or meter error.

In addition to pass/fail classification, the composite accuracy value serves as a tool for calibration traceability. The value can be logged in non-volatile memory alongside metadata such as timestamp, operator ID, serial number of the meter or CT, environmental conditions, and test configuration. This log entry forms a traceable record that supports regulatory audits, type test reports, and manufacturing quality control documentation. In production or laboratory environments, the accuracy value may be associated with a certificate of compliance issued for each device or assembly.

The system may also be used in field service applications to assess ongoing measurement reliability. By periodically recomputing and comparing the composite accuracy value over time, drift in performance can be detected, helping to schedule predictive maintenance or verify that long-installed systems continue to meet operational standards. This is especially valuable in installations exposed to temperature fluctuations, magnetic disturbances, aging components, or mechanical degradation.

To support these functions, the result may be output through one or more diagnostic or communication interfaces integrated into the system. These interfaces may include optical ports, serial buses (e.g., RS-232, RS-485), USB connections, wireless protocols (e.g., Bluetooth, NFC), or network-based communication such as Ethernet or Modbus TCP. The data may be transmitted in raw numerical form, encoded in diagnostic protocol frames, or formatted for display on a user interface such as an LCD screen or graphical terminal. For integration into supervisory systems, the output may be formatted according to utility data standards or test automation frameworks.

In some embodiments, the accuracy result may also trigger automatic report generation or integration into a quality management system (QMS), where digital signatures, audit logs, and batch-level analytics are maintained.

Through this process, the composite measurement accuracy value is elevated from a raw computational output to a decision-making metric with direct applications in metrology validation, installation commissioning, and long-term system integrity monitoring. The method described ensures traceable, repeatable, and actionable use of measurement results in both factory and field environments.

In one preferred embodiment of the method, the accuracy verification process is extended to include the measurement of CT ratio error, phase displacement, and energy deviation under a plurality of predefined combinations of load current and power factor conditions. This extended evaluation is designed to simulate the dynamic operating behavior of the electricity metering assembly more accurately than single-point testing and to reflect the composite accuracy across a realistic range of field operating scenarios.

To implement this embodiment, a test plan is first defined, comprising a matrix of operating points that span a range of current amplitudes and power factor conditions. The load current may be selected from several representative values, for example, 10%, 50%, and 100% of the CT's rated primary current. These current levels are supplied by a programmable current source or a precision current injection system with traceable accuracy. Each current level is applied to the primary conductor of the CT, which in turn produces a secondary current measured by the system as described in Block 102.

For each current level, multiple power factor conditions are simulated by introducing controlled phase shifts between the voltage and current waveforms. This is accomplished using a power calibrator, digital signal generator, or adjustable reactive load bank capable of delivering lagging, leading, and unity power factors. Example power factors include unity (1.0), 0.9 lagging, 0.5 lagging, and 0.8 leading. Each power factor is selected based on typical usage environments for metering applications, such as residential, commercial, or industrial installations where non-unity power factors frequently occur due to inductive or capacitive loads.

During each test point, defined by a unique combination of current level and power factor, the CT ratio error is determined by comparing the measured secondary current against the theoretical secondary current, as calculated from the applied primary current and nominal turns ratio. The phase displacement is measured using the method described in Block 106, ensuring that the angular error introduced by the CT is captured for each test condition. In parallel, the electricity meter records the active energy delivered over a controlled time interval. This energy reading is compared to that of a calibrated reference meter operating under the same conditions, allowing the energy deviation to be computed.

The result of this process is a set of error values for each operating point: CT ratio error, phase displacement error (converted to an equivalent energy error), and energy deviation. For example, if three current levels and three power factors are used, nine distinct operating points are tested, and nine sets of error components are generated.

Once the data set is collected, a computation unit calculates the composite measurement accuracy value by aggregating the results across all operating points. The aggregation may be performed using a variety of mathematical approaches. In one preferred implementation, a root-mean-square (RMS) aggregation is used, whereby the weighted square of each composite error component is summed across all test points, and the square root of the average is taken:

$${S}_{1} = \sqrt{\frac{1}{n} {{\sum }_{i}}^{n} ( {ω}_{1} \cdot {E}_{1 , i}^{2} + {ω}_{2} \cdot {E}_{2 , i}^{2} + {ω}_{3} \cdot {E}_{3 , i}^{2} )}$$

In this equation, S₁ is the final composite measurement accuracy value; E_{1,i}, E_{2,i}, E_{3,i} represent, respectively, the CT ratio error, phase displacement error, and energy deviation measured at the i-th operating point; ω₁, ω₂ and ω₃ are the weighting coefficients selected according to application-specific metrology sensitivity; n is the total number of test points evaluated.

Alternative aggregation strategies may include a load-profile-weighted average, in which each operating point is assigned a weight corresponding to its frequency of occurrence in a typical field deployment scenario. This approach may be particularly useful in smart metering systems where load profile data are available.

The resulting value S₁ represents an aggregate accuracy metric that reflects how the metering assembly performs under dynamic load and power factor variations. This method is significantly more representative of real-world performance than conventional fixed-point accuracy testing, and provides improved assurance that the CT and meter combination will meet accuracy requirements across a full range of practical operating conditions.

This embodiment is particularly advantageous in factory testing, type certification, and field audit environments where regulators, utilities, or manufacturers require comprehensive verification of metering performance under diverse electrical conditions.

In one embodiment of the invention, the composite measurement accuracy value is calculated not as a single static result based on one set of operating conditions, but rather as a time-weighted average derived over a predetermined test period. During this period, the CT ratio error, phase displacement error, and energy deviation are continuously monitored in real time or at fixed sampling intervals. This approach enables the system to reflect the cumulative performance of the metering assembly over varying load conditions, as they would occur during actual deployment.

To implement this embodiment, the verification system initiates a measurement session for a defined duration, referred to as the test period. The length of this period may vary depending on the desired resolution and the range of operating conditions intended to be captured, but in most cases, it can range from several minutes to multiple hours. Throughout the test period, the system captures and processes error data in sequential time segments, with each segment representing a fixed time window (e.g., one second, five seconds, or one cycle of the power waveform).

Within each time segment, the system acquires the current CT ratio error, phase displacement, and energy deviation using the measurement and processing methods previously described in Blocks 104, 106, and 108. These error values are stored in memory along with a time-stamp and the instantaneous magnitude of the load current observed during the same interval. The load current may be derived from a current sensing element placed on the primary or secondary side of the CT and is recorded as an RMS value or peak amplitude. These data are retained as a log of timestamped error values and corresponding load current magnitudes.

The computation unit then processes the log data to calculate the time-weighted composite measurement accuracy value, reflecting the metering assembly's average accuracy over the entire test period. The key to this calculation is the assignment of weighting factors to each time segment based on two criteria: the duration of the time segment and the magnitude of the load current during that segment. These weightings are necessary because the metering error has a more significant practical effect during periods of high current flow than during low-load conditions. Likewise, longer-duration segments should carry more influence than brief transients.

A preferred implementation uses a normalized load-current-time product as the weighting factor for each time segment. For a test period divided into n equal-length time segments, the computation proceeds as follows. Let:
Eᵢ be the composite error calculated at time segment i,
Iᵢ be the RMS load current during time segment i,
Tᵢ be the duration of time segment i (in seconds),
Wᵢ=Iᵢ×Tᵢ be the raw weight for segment i,
S₂ be the final time-weighted composite measurement accuracy.

Then the accuracy value S₂ is calculated as:

$${S}_{2} = \frac{{\sum }_{i = 1}^{n} ( {E}_{1} \cdot {W}_{i} )}{{\sum }_{i = 1}^{n} {W}_{i}}$$

This formula ensures that periods of high load and long duration contribute more significantly to the final result than short, low-load intervals. The use of real-time load current values as part of the weighting factor allows the final value to reflect the relative energy impact of each segment's error.

The value Eᵢ in each segment may be derived from the same root-mean-square-based composite error formulation described in Block 110, combining the CT ratio error, phase displacement, and energy deviation observed in that specific segment. For example, in each time segment, the composite error may be computed as:

$${E}_{i} = \sqrt{{ω}_{1} \cdot {E}_{1 , i}^{2} + {ω}_{2} \cdot {E}_{2 , i}^{2} + {ω}_{3} \cdot {E}_{3 , i}^{2}}$$

where E_{1,i}, E_{2,i}, E_{3,i} are the individual error components for that segment, and ω₁, ω₂, and ω₃ are predetermined weighting coefficients that reflect the contribution of each component to total system accuracy.

To execute the method, the computation unit must be configured to buffer incoming data, compute per-segment error metrics, accumulate weighted products, and normalize the result over the full measurement period. This may be achieved using firmware executed on an embedded processor, a digital signal processor, or a test automation script in a desktop or laboratory environment. Error handling routines may be incorporated to discard segments with corrupted or missing data, and synchronization logic may ensure consistent timing across all input channels.

This embodiment provides a more representative accuracy assessment for metering systems operating in real-world dynamic environments, where load conditions fluctuate continuously. By weighing accuracy measurements over time and current magnitude, the method delivers a single output value that captures long-term, load-weighted accuracy performance of the metering assembly. This is particularly valuable for applications such as factory acceptance testing, long-duration field audits, or embedded diagnostic routines in intelligent meters or data concentrators.

In one embodiment, the method further includes identifying which of the three principal error components—CT ratio error, phase displacement error, or energy deviation—has the greatest influence on the computed composite measurement accuracy value, and producing a corresponding calibration guidance output to assist in corrective action. This feature allows the user or automated system to isolate the source of metering inaccuracy and prioritize the appropriate calibration or maintenance procedure, thereby improving the efficiency and effectiveness of accuracy verification and tuning workflows.

To implement this functionality, the system first calculates the composite measurement accuracy value as previously described, using a mathematical expression that combines the three error components with predetermined weights. In a preferred embodiment, the composite value S is computed using a quadratic combination:

S=\sqrt{w₁×E₁²+w₂×E₂²+w₃×E₃²}

In this equation, E₁, E₂, and E₃ are the CT ratio error, the phase displacement error (converted to an equivalent energy error under a representative power factor, such as 0.5 lagging), and the meter energy deviation, respectively. The coefficients w₁, w₂, and w₃ represent the weighting factors assigned to each error type, based on their respective influence on the final energy measurement under applicable standards or utility-specific requirements.

Once the composite measurement accuracy value has been calculated, the system proceeds to analyze the contribution of each individual error component to the overall composite value. To perform this analysis, the squared contribution of each component is individually evaluated and normalized relative to the total weighted sum of squares. Specifically, the normalized contribution Cⱼ of each error component Eⱼ computed as:

$${C}_{j} = \frac{{w}_{j} \cdot {E}_{j}^{2}}{{w}_{1} \cdot {B}_{1}^{2} + {w}_{2} \cdot {E}_{2}^{2} + {w}_{3} \cdot {E}_{3}^{2}}$$

for j=1, 2, 3, corresponding to the CT ratio error, phase displacement error, and energy deviation, respectively. Each Cⱼ represents the fractional influence of the associated error component on the total composite measurement error.

After computing the normalized contributions, the system performs a comparison to determine which of the three error components exhibits the highest contribution. The error component associated with the largest Cⱼ value is deemed the dominant contributor to the composite accuracy result. For example, if C₂ is greater than both C₁ and C₃, the phase displacement error is identified as the dominant factor.

Upon identifying the dominant contributor, the system generates a calibration guidance output, which is used to inform the operator, test engineer, or calibration software regarding the corrective action that should be prioritized. This output may take the form of a text message, graphical indicator, flag, or command issued to an external calibration station. Example outputs include:
(1) “Primary cause of inaccuracy: CT amplitude error. Recommend CT gain adjustment or replacement.”
(2) “Dominant contributor: Phase displacement error. Verify CT orientation and minimize load-side reactance.”
(3) “Meter energy deviation exceeds threshold. Suggest meter recalibration or reference comparison.”

The calibration guidance output may be displayed on a graphical user interface (GUI), exported to a log file, embedded into a diagnostic communication frame (e.g., via Modbus, DLMS, or IEC 61850), or stored in a local or cloud-based asset management database.

The analysis and output generation logic may be implemented as part of the same computation unit described in earlier blocks, or as a secondary module within a diagnostic or control subsystem. In either case, the logic may be executed in real time immediately after the composite value is computed, or batch processed at the end of a test cycle. Optionally, the system may also record historical dominant contributors across test sessions to track stability or degradation trends for each component type.

This embodiment is particularly valuable in environments where fast, field-level diagnostics are required, such as utility meter installation audits, mobile test labs, factory end-of-line tests, or remote monitoring systems for substation equipment. By identifying the primary source of error and delivering targeted calibration recommendations, the method significantly reduces diagnostic time, improves corrective precision, and supports compliance with regulatory accuracy standards.

In one embodiment, the method further comprises comparing the computed composite measurement accuracy value to a predefined compliance threshold and classifying the metering assembly as passing or failing based on whether the computed value falls within the specified acceptable range. This feature is designed to automate the decision-making process that determines whether a given electricity meter and current transformer (CT) combination meets regulatory or application-specific accuracy requirements.

The composite measurement accuracy value is obtained as described in previous steps. This value, denoted as S, reflects the combined contribution of CT ratio error, phase displacement error, and energy deviation. It is typically expressed as a percentage and quantifies the total expected deviation of energy measurement performance for the meter-CT assembly under the tested conditions.

A compliance threshold is established in advance and stored in the system memory or configuration database. This threshold represents the maximum allowable composite error value for the metering system to be considered acceptable. The threshold value may correspond to an industry accuracy class standard, such as Class 0.5, Class 1.0, or a utility-specific benchmark. For instance, a threshold of 0.5% may be used to verify compliance with IEC 62053-22 or ANSI C12.20 accuracy standards for active energy meters in commercial billing environments.

The comparison is executed using a simple conditional logic operation. The computation unit retrieves the threshold value, compares it with the calculated composite accuracy value S, and evaluates whether the condition:

S≤Threshold
is satisfied. If the condition holds true, the metering assembly is classified as passing, indicating that the combination of CT and meter meets or exceeds the defined accuracy requirements under the tested conditions. If the condition is false—i.e., the computed composite error exceeds the threshold—the system classifies the assembly as failing, indicating that it does not meet the required measurement performance.

This classification result is then encoded as a binary status output, a diagnostic flag, or a user-facing message. The output may be represented in several formats depending on the implementation. For example:
(1) In a graphical user interface (GUI), a green check mark or “PASS” label may be displayed for compliant systems, while a red cross or “FAIL” label is shown for non-compliant systems.
(2) In automated calibration software, a Boolean flag (e.g., is_pass=TRUE/FALSE) may be generated and logged with the associated test record.
(3) In a production test bench, the result may be used to trigger the sorting of tested units into pass/fail bins using mechanical relays or indicators.
(4) In remote diagnostics, the pass/fail classification may be transmitted over a data link (e.g., Modbus, TCP/IP, or DLMS) as part of a structured diagnostic report or uploaded to a cloud-based test results repository.

To ensure traceability, the classification result is stored along with the composite error value, timestamp, test configuration parameters (e.g., CT model, meter ID, applied current, power factor), and operator or station identifier. This enables full auditability of the test results and supports compliance reporting, quality assurance reviews, or warranty validation procedures.

Optionally, the system may allow for multiple thresholds to be defined for different test modes or regulatory contexts. For example, one threshold may be used during initial factory calibration, another during installation audits, and a third during periodic field re-verification. The threshold may also be dynamically selected based on metadata associated with the tested assembly (e.g., accuracy class code, rated burden, or CT class type).

This pass/fail classification mechanism enables standardized, objective evaluation of metering accuracy performance, ensuring that only assemblies that conform to required measurement tolerances are approved for deployment, billing, or regulatory certification. It eliminates the need for manual inspection of raw error values and supports real-time, repeatable decisions that can be scaled across automated test environments.

In one embodiment of the method, the computed composite measurement accuracy value and the associated classification result—indicating whether the metering assembly has passed or failed the accuracy threshold—are further encoded into a diagnostic data record. This record is made retrievable via a digital interface, enabling its use in quality assurance (QA) systems, automated test benches, field commissioning tools, or remote inspection platforms.

Once the composite measurement accuracy value S is calculated as described in previous blocks, and the metering assembly is classified as either “PASS” or “FAIL” according to the threshold evaluation, these outputs are structured into a formal data representation referred to as a diagnostic record. This record may be implemented as a JSON object, an XML document, a binary data structure, or a protocol-compliant data frame, depending on the communication method and integration environment.

The diagnostic record includes at minimum the following fields:
(1) Timestamp: A date-time identifier representing when the test was conducted;
(2) Meter Serial Number or ID: A unique identifier for the electricity meter under test;
(3) CT Serial Number or ID: A unique identifier for the CT used in the assembly;
(4) Composite Measurement Accuracy Value(S): The calculated error percentage;
(5) Classification Result: A pass/fail flag or code indicating compliance with the predefined threshold;
(6) Test Parameters: Optional metadata including the applied current level, power factor, voltage, ambient temperature, duration of test, and selected threshold class;
(7) Test Station ID/Operator ID: Information used for traceability and audit.

These fields may be defined in a pre-established data schema and encoded using a standard serialization technique. For example, in an embedded implementation using a UART or RS-485 digital interface, the diagnostic record may be encoded as a Modbus RTU data packet or as a binary payload with fixed field lengths. In Ethernet-enabled systems, the record may be transmitted over TCP/IP using HTTP or MQTT protocols with JSON-formatted content. In high-accuracy test benches, the record may be embedded within IEC 61850, DLMS/COSEM, or proprietary SCADA protocols.

Once the diagnostic data record is constructed, it is stored in local memory—such as non-volatile EEPROM, flash memory, or RAM—temporarily or permanently, depending on system configuration. A buffer management routine ensures that records are retained until acknowledged or uploaded.

To make the record retrievable, a digital interface is exposed to external systems. This interface may be physical (e.g., USB, RS-232, RS-485, Ethernet, optical port) or wireless (e.g., BLE, NFC, Wi-Fi, LoRa). An external QA terminal, field calibration tool, or supervisory computer can issue a query command, prompting the system to return the stored diagnostic record via the selected interface. In some cases, the data may be streamed in real time to a connected device without requiring manual polling.

The diagnostic record may be:
(1) Logged locally for later extraction (e.g., by service personnel using a handheld tool);
(2) Pushed remotely to a centralized calibration database or quality assurance system via network connection;
(3) Displayed on screen to an operator during a production test;
(4) Archived in compliance logs to support audit trails, regulatory reporting, or performance history analysis.

To ensure data integrity, the system may apply validation logic such as checksums, CRCs, or digital signatures. Encryption may be used to protect sensitive calibration results during transmission, particularly in regulated environments or cloud-connected metering infrastructures.

By encoding both the numerical accuracy result and the pass/fail classification in a structured record, and providing automated retrieval via digital interface, this embodiment enhances transparency, traceability, and automation in metering accuracy testing workflows. It enables seamless integration with modern test management software and supports the needs of high-volume production environments, third-party inspection agencies, and utility calibration programs.

In one embodiment, the method further includes detecting a polarity or phase reversal of the current transformer (CT) by analyzing the direction and phase alignment of the CT's measured secondary current relative to the known or expected characteristics of the primary current. Upon identification of a reversal condition, the method includes either applying a polarity correction in the processing logic or flagging the metering assembly for installation error, depending on whether automatic correction is permitted or whether operator intervention is required.

In normal operation, a CT is installed such that its secondary current waveform maintains a known and expected phase relationship with the primary current. Specifically, under ideal installation conditions, the CT secondary current should lag the primary current by a minimal and predictable phase angle (typically due to magnetizing inductance and internal burden characteristics), and the waveform polarity should be consistent with the expected current direction based on the CT's orientation.

If the CT is installed backwards—that is, if the primary conductor passes through the CT core in the wrong direction or the secondary wiring is reversed, the measured secondary current will exhibit an inverted polarity and/or a 180-degree phase shift relative to the primary current. This condition introduces substantial error into metering calculations, especially in systems that depend on correct quadrature alignment for power factor or active/reactive energy computations.

To detect such reversal conditions, the system simultaneously acquires the primary and secondary current waveforms using synchronized analog-to-digital converters (ADCs) or equivalent time-aligned sampling methods. The primary current may be obtained from a reference current source or from a known injection profile. The secondary current is measured by a high-precision sensing component, as described in Block 102.

The detection algorithm compares the instantaneous polarity, waveform shape, and zero-crossing timing of the two current waveforms. If the two waveforms are out of phase by approximately 180 degrees—that is, if their zero-crossings and peaks occur in opposite directions—or if their phase difference exceeds a predefined tolerance band (e.g., ±150 to ±210 degrees), the system determines that a polarity or phase reversal has occurred.

This evaluation may be executed by computing the cross-correlation of the two signals, the sign of their dot product, or by directly calculating the relative phase angle using a fast Fourier transform (FFT), Hilbert transform, or zero-crossing interval analysis. In a simplified implementation, the sign of the RMS or instantaneous current product (i.e., Iₚᵣᵢ₍ₜ₎×I_{sec(t)}) may be analyzed over one or more cycles to infer relative polarity.

Once a reversal is detected, the system initiates a response mechanism. In embodiments where software-based correction is permitted, the system may apply a polarity inversion correction to the secondary current waveform before using it in further calculations. This correction consists of multiplying the measured secondary current signal by −1 and recalculating all derived quantities, such as CT ratio error and phase displacement, using the corrected polarity.

In other embodiments, especially in field installations where such correction may mask a wiring fault, the system does not automatically correct the polarity, but instead flags the metering assembly for installation error. This is done by generating a diagnostic warning or fault code, which may be recorded in a test log, shown on a display interface, or transmitted to a central monitoring system via a digital communication protocol. A sample diagnostic message may be: “CT Polarity Reversal Detected-Check Installation Orientation.”

In either case, the polarity or phase reversal detection logic may be executed in real-time as part of the accuracy verification cycle, or may be invoked as a pre-check step before proceeding with full composite accuracy measurement. It may also be repeated periodically in long-term metering applications to detect changes due to field rewiring, maintenance error, or component replacement.

This feature is critical to ensuring the validity of all subsequent accuracy measurements, as undetected polarity reversals can completely invalidate energy readings, produce incorrect billing results, and obscure other calibration errors. By incorporating automatic detection, correction, or flagging of CT reversal conditions, the disclosed method significantly enhances the robustness and reliability of metering accuracy validation, particularly in high-volume manufacturing, utility deployment, or service commissioning environments.

In one embodiment of the invention, the method further comprises compensating the CT ratio error, phase displacement error, and energy deviation based on a detected ambient temperature, such that the composite measurement accuracy value is computed using temperature-adjusted error values. This embodiment is intended to reflect the influence of thermal variations on metering performance and to produce an accurate result that more accurately represents the metering assembly's behavior under real-world environmental conditions.

It is well understood in the field of metrology that the electrical and magnetic properties of current transformers (CTs) and energy meters are sensitive to ambient temperature. For example, the magnetic permeability of the CT core material, the winding resistance, and the dielectric properties of internal insulation may vary as the temperature deviates from the standard reference condition (typically 23 °C±2 °C). Similarly, the gain, offset, and phase characteristics of analog signal conditioning circuitry in the meter may drift with temperature changes, leading to measurable error shifts in energy calculation.

To address these effects, the method includes the integration of a temperature measurement component into the verification system. This component may be a digital temperature sensor (e.g., I²C or SPI thermistor), an analog temperature transducer (e.g., a thermocouple or RTD), or an integrated temperature monitoring circuit within the electricity meter itself. The sensor is positioned to measure the ambient temperature surrounding the metering assembly during the test or verification process. In some implementations, the temperature may be averaged overtime or monitored continuously during the test interval.

The detected ambient temperature value is sampled and supplied to the processing unit or computation unit, which is configured to apply temperature compensation functions to each of the individual error components prior to computing the composite measurement accuracy value.

Each of the three principal error components is compensated as follows:

### (1) CT Ratio Error Compensation:

A temperature correction factor is applied to the measured CT ratio error to account for thermal drift in the CT's magnetization characteristics and secondary winding resistance. The compensation function may be implemented as a linear or polynomial equation derived from factory calibration data, or as a look-up table indexed by temperature. For example:

$${E}_{1}^{adj} = {E}_{1} + Δ {E}_{1} ( T )$$

where E is the measured CT ratio error, T is the ambient temperature, and ΔE₁(T) is the temperature correction value retrieved or calculated for the given temperature.

$${E}_{1}^{adj}$$

represents the temperature-compensated CT ratio error, reflecting the expected transformation accuracy of the current transformer at the measured ambient temperature rather than at nominal laboratory conditions.

### (2) Phase Displacement Error Compensation:

The phase displacement error is also corrected to account for changes in the magnetic phase lag introduced by the CT core at different temperatures. A correction offset or scale factor is applied to the measured phase displacement angle (or the equivalent energy error derived from it). The compensated value

$${E}_{2}^{adj}$$

is then used in composite accuracy calculations.

### (3) Energy Deviation Compensation:

The meter's internal measurement error is corrected based on a thermal model or characterization curve that relates the meter's measurement deviation to temperature. This compensation may correct for gain drift, clock frequency shifts, or analog front-end nonlinearity as a function of temperature. The corrected value

$${E}_{3}^{adj}$$

represents the temperature-normalized energy deviation.

Each of these adjusted error components is then used to compute the final temperature-compensated composite measurement accuracy value S_{adj}, using the same weighted RMS combination previously defined:

$${S}_{adj} = \sqrt{{w}_{1} \cdot {( {E}_{1}^{adj} )}^{2} + {w}_{2} \cdot {( {E}_{2}^{adj} )}^{2} + {w}_{3} \cdot {( {E}_{3}^{adj} )}^{2}}$$

The weighting coefficients w₁, w₂, and w₃ may remain fixed or may themselves be modified based on the operating temperature, depending on the desired precision. The adjusted value S_{adj} now reflects the true expected accuracy performance of the meter-CT assembly at the tested ambient temperature rather than at the nominal laboratory reference condition.

This compensation process may be performed in real time or post-processed after data acquisition. In a production test environment, the system may log both the uncorrected and corrected composite accuracy values to support traceability. In a field diagnostic tool, the compensation function enables a more accurate assessment of metering accuracy during field commissioning or troubleshooting, particularly in climates where ambient temperature can differ significantly from laboratory conditions.

This embodiment is particularly useful in outdoor or utility environments where ambient temperatures may range from −40 °C to +70 °C, and where accuracy certification at nominal temperature alone does not reflect true in-service performance. By incorporating temperature-adjusted corrections to each contributing error component, the system delivers a more robust and representative evaluation of metering accuracy under real-world operating conditions.

In one embodiment, the method further includes repeating the computation of the composite measurement accuracy value at predefined time-based or usage-based intervals and comparing the newly computed result with historical values to detect long-term degradation in the accuracy of the electricity metering assembly. This process enables ongoing monitoring of measurement performance over time, facilitating early identification of drift or deterioration due to aging, temperature cycles, environmental stress, or component wear.

To begin, the system is programmed to initiate recalculations of the composite accuracy value based on either of two types of triggers:

The first type is a scheduled time interval, which could be daily, weekly, monthly, or any configurable period, depending on the criticality of the metering installation. A real-time clock or timer embedded in the system keeps track of elapsed calendar time, and when the preset duration has passed since the last verification, the process is re-executed.

The second type is an operating-hours-based interval, where the composite measurement accuracy is recomputed after the meter has accumulated a specified number of active usage hours. This is determined by tracking the amount of time the meter is energized, or optionally, the number of ampere-hours or kilowatt-hours that have been measured by the system. When the accumulated usage exceeds the defined threshold, the system begins a new verification cycle.

Each time the process is triggered, the system measures the current CT ratio error, phase displacement error, and meter energy deviation under operating or reference conditions. These errors are processed to derive a fresh composite measurement accuracy value using the same methodology employed during initial verification. The composite value represents the combined influence of the three sources of error and provides a snapshot of the current performance of the metering assembly.

Following the new computation, the system retrieves one or more previously stored composite accuracy values from non-volatile memory or a diagnostic database. Each stored value is typically associated with a timestamp, meter ID, and test condition metadata. These historical values serve as a reference against which the newly computed value is compared.

The comparison process involves evaluating how much the new accuracy value has changed relative to prior results. The system determines whether there is a trend of increasing error, which would suggest that the performance of the meter or CT is deteriorating over time. This may include a simple comparison between the most recent result and the baseline recorded during factory testing or earlier field calibration.

If the system identifies a change that exceeds a predefined threshold—such as a progressive increase in composite error—the system will flag the result for inspection, generate an alert, or mark the metering assembly for recalibration. In some implementations, a diagnostic warning may be displayed to the user or transmitted to a remote monitoring platform. The flag may also be used internally to delay certification, suspend billing authorization, or trigger further diagnostics.

The implementation of this process may be handled entirely within the firmware of a smart meter, in a companion diagnostic device, or in an external system such as a utility data concentrator or centralized test bench controller. The system maintains an indexed storage of previous values and continuously updates it each time a new verification cycle is completed.

The described method enables lifecycle monitoring of electricity metering assemblies in the field, providing a structured mechanism to detect performance drift due to gradual degradation. This is particularly valuable in long-term deployments, where periodic re-verification is mandated by regulatory authorities or operational best practices. By enabling consistent, interval-based tracking of metering accuracy, this embodiment enhances the reliability, compliance, and maintainability of power metering systems deployed in utility, industrial, and commercial environments.

Embodiments of the teachings of the present disclosure have been described in an illustrative manner. It is to be understood that the terminology that has been used, is intended to be in the nature of words of description rather than of limitation. Many modifications and variations of the embodiments are possible in light of the above teachings. Therefore, within the scope of the appended claims, the embodiments can be practiced other than specifically described.

What is claimed is:

1. A method for verifying the composite measurement accuracy of an electricity metering assembly comprising an electricity meter and a current transformer (CT), the method comprising:
measuring, by at least one current sensing component, a secondary current output from the CT under defined load conditions;
determining, by a processing unit, a ratio error of the CT based on a comparison between the measured secondary current and a theoretical secondary current derived from a known primary current;
measuring a phase displacement between the primary current and the secondary current of the CT using a phase angle detection unit;
acquiring, by the electricity meter, energy measurement values under reference operating conditions including voltage, current, frequency, power factor, and temperature parameters;
computing a composite measurement accuracy value based on the determined CT ratio error, the measured phase displacement, and a deviation between the acquired energy measurement values and expected reference values; and
using the computed composite measurement accuracy value to support verification of installation quality, facilitate calibration traceability, or assess ongoing measurement reliability.

2. The method of claim 1, wherein computing the composite measurement accuracy value comprises:
calculating a composite measurement accuracy value S using the following formula:
S=\sqrt{w₁×E₁²+w₂×E₂²+w₃×E₃²}
wherein E₁ is the CT ratio error, defined as the percentage difference between the measured secondary current output from the CT and a theoretical secondary current calculated by dividing the primary current, measured by a reference current source, by the CT turns ratio; E₂ is the phase displacement error, defined as the percentage contribution of the angular displacement, in degrees, between the primary and secondary current waveforms, to active energy measurement error at a power factor of 0.5 lagging; E₃ is the energy deviation, defined as the percentage difference between the energy measured by the electricity meter under controlled reference conditions and the energy value measured by a calibrated reference meter under the same voltage, current, frequency, and power factor conditions; w₁, w₂, and w₃ are predetermined coefficients, each selected based on standardized sensitivity coefficients defined in metering accuracy test procedures for active energy, corresponding respectively to the CT ratio error, phase displacement error, and meter energy deviation.

3. The method of claim 1, wherein the CT ratio error, phase displacement, and energy deviation are measured under multiple combinations of load current and power factor conditions, and the composite measurement accuracy value is calculated as an aggregate result across the different conditions to simulate dynamic operating behavior of the metering assembly.

4. The method of claim 1, wherein the composite measurement accuracy value is calculated as a time-weighted average over a predetermined test period, during which the CT ratio error, phase displacement, and energy deviation are continuously monitored, and the weighting for each time segment is based on the duration and magnitude of the load current during that segment.

5. The method of claim 1, further comprising identifying which of the CT ratio error, the phase displacement error, or the energy deviation is the dominant contributor to the composite measurement accuracy value, and generating a calibration guidance output indicating the measurement component that should be prioritized for correction.

6. The method of claim 1, further comprising comparing the computed composite measurement accuracy value to a predefined compliance threshold, and classifying the metering assembly as passing or failing based on whether the value is within the acceptable limit.

7. The method of claim 1, further comprising encoding the composite measurement accuracy value and classification result into a diagnostic data record, which is retrievable via a digital interface for quality assurance logging or remote inspection.

8. The method of claim 1, further comprising detecting a polarity or phase reversal of the current transformer by analyzing the direction and phase alignment of the measured secondary current relative to the primary current, and, upon detection of a reversal condition, applying a polarity correction or flagging the metering assembly for installation error.

9. The method of claim 1, wherein the CT ratio error, phase displacement error, and energy deviation are compensated based on a detected ambient temperature, and the composite measurement accuracy value is computed using the temperature-adjusted error values to reflect operating conditions of the metering environment.

10. The method of claim 1, further comprising repeating the computation of the composite measurement accuracy value at scheduled intervals or after predefined operating hours, and comparing the current value with previously computed values to detect long-term accuracy degradation of the metering assembly.
